(19) United States
(12) Patent Application Publication
(10) Pub. No.: US 2015/0334856 A1
(43) Pub. Date: Nov. 19, 2015

(54) TEAR-AWAY ARC FAULT RELIEF PANEL FOR ELECTRICAL CABINET

(71) Applicant: Sanmina Corporation, San Jose, CA (US)

(72) Inventors: Glen Gommels, Scottsdale, AZ (US); Eric Pryor, Union City, CA (US)

(21) Appl. No.: 14/711,760

(22) Filed: May 13, 2015

Related U.S. Application Data
(60) Provisional application No. 61/992,762, filed on May 13, 2014.

(51) Int. Cl. H05K 5/02; H05K 7/20

(52) U.S. Cl. CPC H05K 5/0213; H05K 7/20

(57) ABSTRACT

In one aspect, an arc fault relief panel is provided for mounting to a cabinet for enclosing medium- or high-voltage electrical equipment. The panel includes bend relief cuts or slots to allow the panel to fail in a predictable manner during an explosive arc fault. That is, the cuts or slots provide weakened locations or segments along the panel that permit a main portion of the panel to bend outwardly during an explosive arc fault. The main portion of the panel may be secured to other components of the cabinet with tear-away fasteners. During an explosive arc fault, the panel tears away from the fasteners, allowing the panel to bend outwardly along its weakened segments to provide an opening for venting pressurized air. A lanyard cable may be used to restrict outward movement of the main portion of the panel to help protect adjacent equipment or nearby personnel.

### CLAIM OF PRIORITY

The present application claims priority to U.S. Provisional App. Ser. No. 61/992,762, filed May 13, 2014.

### FIELD

Various features relate to cabinets for enclosing electrical equipment and, in particular, to cabinets provided with arc fault pressure relief components.

### BACKGROUND

An arc fault or arc flash is a high power discharge of electricity between two or more conductors that may occur in an electrical device enclosed within a cabinet or chassis. Such faults may be caused by faulty connections arising due to corrosion or as a result of a faulty initial installation. A sufficiently large arc fault can trigger a sudden burst of air pressure within the cabinet (i.e. an explosion) that can damage the cabinet and its components. If sufficiently severe, the explosion can eject portions of the cabinet at high speed, potentially injuring individuals in the vicinity and/or damaging nearby equipment. Existing mechanisms for releasing or venting the pressure of an arc fault, such as exhaust vents, can allow dust to intrude into the cabinet and/or render the electrical components more prone to corrosion from humidity. Therefore, there is a need for improved arc fault pressure relief components or mechanisms.

### SUMMARY

In one aspect, a cabinet for electrical components includes: an enclosure to enclose the electrical components and an arc fault relief panel to relieve air pressure during an explosive arc fault, wherein the arc fault relief panel is adapted to be forcibly deformed by an air pressure burst from an explosive arc fault to allow the panel to open and relieve pressure within the cabinet.

In an illustrative example, the arc fault relief panel includes a weakened portion configured to allow a main portion of the arc fault relief panel to bend away from the enclosure to thereby open and vent air pressure within the cabinet. The weakened portion comprises one or more slots or “bend relief cuts” formed within the arc fault relief panel to permit controlled bending of the main portion of the arc fault relief panel, such as slots formed along edges of the arc fault relief panel. The main portion of the arc fault relief panel may be secured to the enclosure using one or more fasteners mounted within tear-away portions of the panel so that the panel is a tear-away panel. The fasteners may be bolts or screws. The tear-away portion of the arc fault relief panel may be a laser-perforated portion of the panel in which the screws or bolts are mounted. The arc fault relief panel may be mounted to the top or rear of the enclosure and may include restraint devices to restrict a range of movement of the arc fault relief panel during an explosive arc fault. For example, a lanyard cable may be employed. As such, when the panel pops outwardly from an explosive burst of pressure, the panel will not damage adjacent machinery nor injure nearby individuals. That is, one of the functions of the arc fault panel is to direct an arc fault burst away from any operators who may be in the vicinity. Still further, panel stiffeners may be provided along portions of the panel that are not meant to be forcibly deformed to help secure those portions during an explosive arc fault.

In another aspect, an electrical device or apparatus includes: a cabinet having an enclosure to enclose electrical components and an arc fault relief panel to relieve air pressure during an explosive arc fault wherein the arc fault relief panel is adapted to be forcibly deformed by an air pressure burst from an explosive arc fault to allow the panel to open and relieve pressure within the cabinet; and one or more electrical components mounted within the cabinet.

In yet another aspect, a method for providing a cabinet for electrical components includes: forming an enclosure to enclose electrical components; forming an arc fault relief panel to relieve air pressure during an explosive arc fault, wherein the arc fault relief panel is adapted to be forcibly deformed by an air pressure burst from an explosive arc fault to allow the panel to open and relieve pressure within the cabinet; and mounting the arc fault relief panel to the enclosure.

In still yet another aspect, an arc fault relief panel for a cabinet for electrical components includes: an arc fault relief panel configured to relieve air pressure within an enclosure of the cabinet during an explosive arc fault; wherein the arc fault relief panel is adapted to be forcibly deformed by an air pressure burst from an explosive arc fault within the cabinet to allow the panel to open and relieve pressure within the cabinet; and wherein the arc fault relief panel includes at least one tear-away portion for fastening a main portion of the panel to the enclosure of the cabinet.

### BRIEF DESCRIPTION OF THE DRAWINGS

FIG. 1 is a perspective view of an electrical cabinet having a top-mounted tear-away arc fault relief panel.

FIG. 2 is a close-up view of a portion of the top-mounted tear-away arc fault relief panel, particularly showing a bend relief cut and a bend stiffener that allow for controlled bending of the panel during an explosive arc fault.

FIG. 3 is a further close-up view of the top-mounted arc fault relief panel.

FIG. 4 is a close-up view of a tear-away fastener having a screw mounted within a laser-perforated ring forming a shear tab.

FIG. 5 is a close-up view of a tear-away fastener having a bolt mounted within a laser-perforated ring, also forming a shear tab.

FIG. 6 is a perspective view of the electrical cabinet of FIG. 1 with the top-mounted tear-away arc fault relief panel open following an explosive arc fault.

FIG. 7 is a close-up view of a portion of the arc fault relief panel of FIG. 6, particularly showing the bend relief cut, as deformed due to an explosive arc fault.

FIG. 8 is a close-up view of a portion of an inner side of the tear-away arc fault relief panel of FIG. 6, particularly showing a lanyard.

FIG. 9 is a perspective view of the inner side of the tear-away arc fault relief panel of FIG. 6, showing a pair of lanyards and other components.

FIG. 10 is a close-up view of a tear-away fastener of the arc fault relief panel of FIG. 6, particularly showing its laser-perforated ring.

FIG. 11 is a perspective view of an electrical cabinet having a side-mounted tear-away arc fault relief panel having multiple controlled-bend locations.

FIG. 12 is a perspective view of another electrical cabinet having a side-mounted tear-away arc fault relief panel but with only an edge-mounted controlled-bend location.

FIG. 13 is a perspective view of yet another electrical cabinet having a side-mounted tear-away arc fault relief panel, particularly showing a couple of panel stiffeners.

FIG. 14 is a perspective view of the electrical cabinet of FIG. 13, with the side-mounted tear-away arc fault relief panel open following an explosive arc fault.

FIG. 15 is a block diagram, with schematic elements, illustrating components of an electrical device or apparatus with a cabinet having a tear-away arc fault relief panel.

FIG. 16 is a block diagram of the electrical device or apparatus of FIG. 15, shown during an explosive arc fault with the tear-away arc fault relief panel popped open.

FIG. 17 illustrates a method for providing a cabinet for electrical components with a tear-away arc fault relief panel.

FIG. 18 illustrates a method for using a cabinet for electrical components with a tear-away arc fault relief panel.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation.

### Overview

Several novel features pertain to arc fault relief panels (also referred to herein as arc flash or arc blowout panels) for use with cabinets or enclosures for electrical equipment, such as high-voltage equipment. Briefly, in one example, an arc fault relief panel is provided for mounting to, or forming part of, a cabinet for enclosing electrical equipment. The panel includes bend relief cuts or slots to allow the panel to fail in a predictable manner during an explosive arc fault. That is, the cuts or slots provide a weakened portion or segment of the panel that permits a main portion of the panel to bend outwardly during an explosive arc fault. The main portion of the panel is secured to other components of the cabinet with tear-away fasteners, such as screws or bolts mounted within laser-perforated rings. During an explosive arc fault, the panel tears away from the screws or bolts along the perforated rings, allowing the panel to bend or pop outwardly from the cabinet to provide an opening for venting hot and pressurized air during an explosive arc fault. Some of the force of the explosion also serves to deform the metal of the panel, hence absorbing or dissipating some of the blast energy. A lanyard cable connects an inside of the cabinet to the arc fault relief panel to limit movement of the main portion of the panel to protect adjacent equipment or nearby personnel.

Exemplary Electrical Component Cabinets with Arc Fault Relief Panels

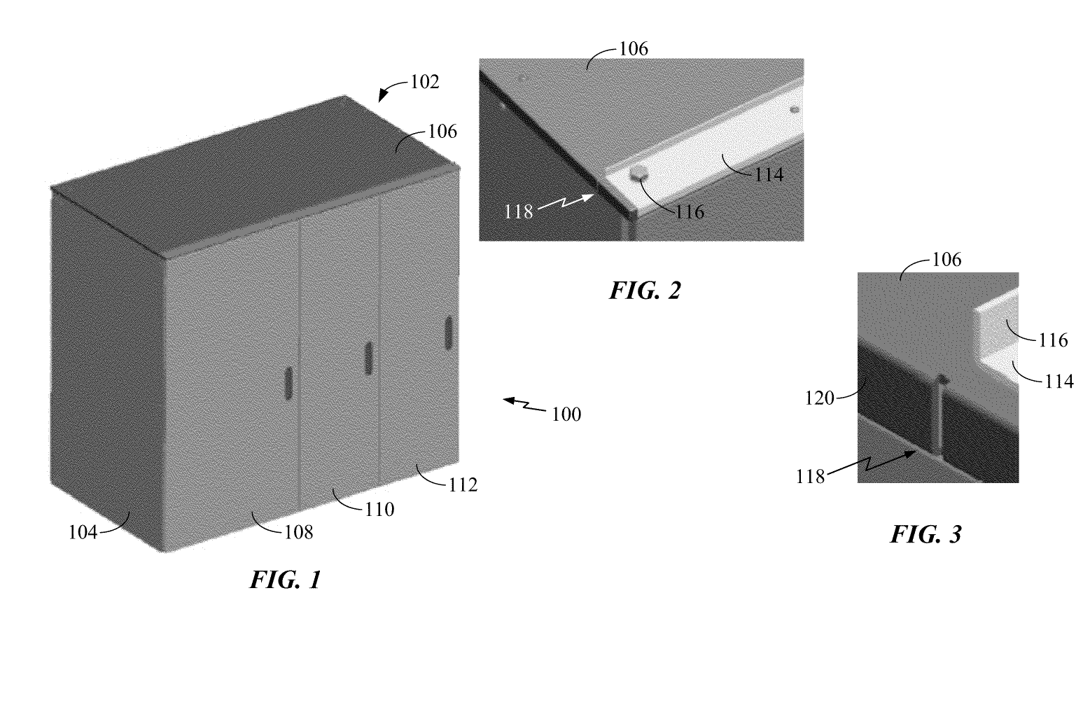

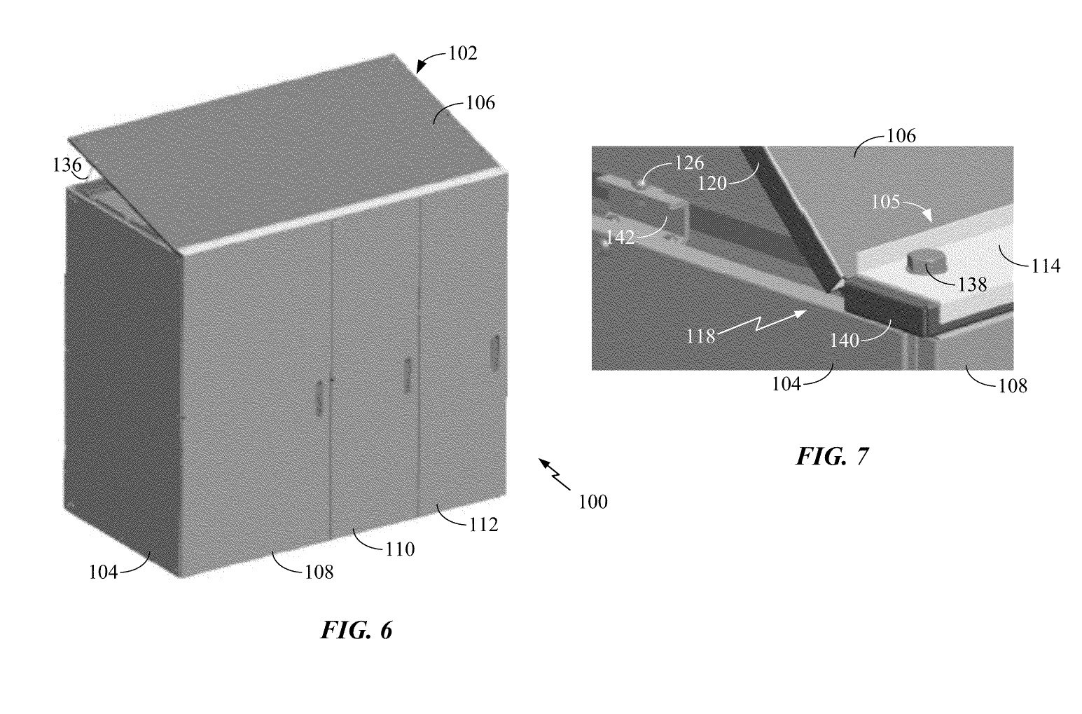

FIG. 1 illustrates a cabinet 100 having a top-mounted arc fault relief panel 102 mounted along a top of a multi-bay enclosure 104 of the cabinet. The cabinet 100 may include medium- or high-voltage electrical equipment not shown in the figure. The metal panel 102 includes a main portion 106 adapted to be bent outwardly during an explosive arc fault within the cabinet to provide an opening for venting pressurized air and heat generated by the arc fault. The arc fault relief panel is shown in its open configuration in FIG. 6. By relieving pressure within cabinet 100, the arc fault relief panel 102 helps protect other portions of the cabinet from damage such as front panel portions 108, 110 and 112, as well as the internal electrical equipment itself. As noted, by relieving pressure that might otherwise explode the cabinet, nearby personnel are also protected along with any adjacent equipment.

FIGS. 2 and 3 more closely illustrate one end of the arc fault relief panel 102, which is mounted to an edge of the cabinet by a bend stiffener 114 via four M12 bolts 116. As can be seen, the bend stiffener 114 includes an upturned flange (or rim) 116. Bend relief cuts or slots 118 are formed vertically along a downward extending flange (or rim) 120 of the arc fault relief panel 102 to selectively weaken the panel to allow it to deform during an explosive arc fault so that the main portion 106 of the panel can tilt or bend upwardly (as shown in FIG. 6). That is, the bend relief cuts 118 allow for a controlled bending or controlled deformation of the arc fault relief panel 102, with the main portion 106 of the panel folding in a predictable and controlled manner along the upturned flange 116 of the stiffener 114. The stiffener also guides the bend of the panel along the predetermined point or line that has been weakened by the cut in the side flange.

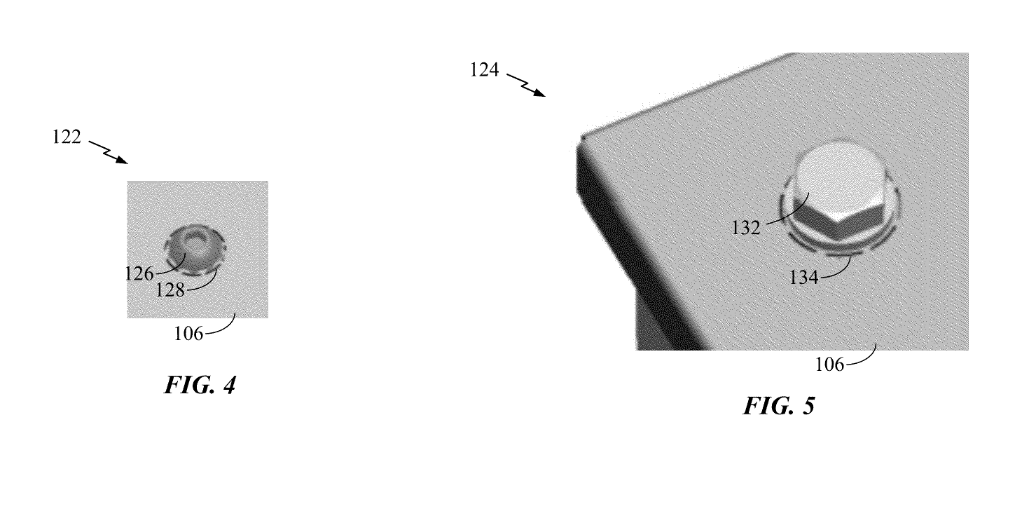

FIGS. 4 and 5 illustrate tear-away fasteners 122 and 124 that may be used to secure the main portion 106 of the arc fault relief panel 102. More specifically, FIG. 4 shows an M6 screw 126 threaded through the center of a laser-perforated ring 128 formed in the main portion 106 of the arc fault relief panel 102. In the illustrative example of FIGS. 1-3, three such screws are provided along each side edge of the main portion 106 of the arc fault relief panel 102. FIG. 5 shows an M12 bolt 132 threaded through the center of a laser-perforated ring 134 also formed in the main portion 106 of the arc fault relief panel 102. In the illustrative example of FIGS. 1-3, one such bolt is provided in each rear corner of the main portion 106 of the arc fault relief panel 102. The force of an explosive arc fault causes the laser-perforated rings to fail, allowing the main portion 106 of the arc fault relief panel to tear away from the cabinet and bend upwardly, as already described. Other techniques may be used to form the weakened ring around the bolts and screws. Laser-perforation is just one example. Insofar as the material of the panel is concerned, any of a wide variety of metals or other materials may be used to fabricate the panel. Typically, the same types of materials used to fabricate the other panels of the cabinet are employed for the arc fault relief panel. However, the thickness and/or strength of the arc fault relief panel may be designed or selected as needed to provide a desired amount of controlled deformation during an explosive arc fault. In this regard, otherwise conventional experiments may be performed to identify preferred or optimal materials and dimensions for use in designing and fabricating the arc fault relief panel.

FIGS. 6 and 7 illustrate the cabinet 100 following an explosive arc fault that caused the arc fault relief panel 102 to open, as shown. In the open configuration, a lanyard 136 is visible in FIG. 6, which connects an interior of the cabinet 102 to an inner surface of the main portion 106 of the arc fault relief panel 102 to restrain or restrict the outward movement of the main portion 106 of the arc fault relief panel 102 during an explosive arc fault. As can be seen in FIG. 7, the bend relief cut 118 has been bent open by the force of the explosion, allowing the main portion 106 of the arc fault relief panel 102 to bend upwardly along a controlled bend portion, segment or location 105 (i.e. along the rear side of the reinforced upturned edge of the stiffener 114). FIG. 7 also shows a bolt 138 used for securing both the stiffener 114 and a front edge or portion 140 of the arc fault relief panel to the front portion of the cabinet. With this configuration, the front portion 140 of the arc fault relief panel 102 is securely sandwiched between the stiffener and the cabinet. Note that bolt 138, and any others mounted along the front of edge the panel, are not tear-away bolts as with those in the rear. That is, no laser-perforations encircle bolt 138. Bolt 138 is instead provided to help securely mount the front edge 140 of the arc fault panel 102 to the cabinet so that only the rear (main) portion 106 of the arc fault panel 102 is torn away from the cabinet during an explosive arc fault.

FIG. 7 also illustrates one of several frame brackets 142 mounted along the side of the cabinet. The aforementioned screws 126 are threaded into the frame brackets 142 through side edges of the arc fault relief panel 102. As already discussed, these screws are mounted through the centers of laser-perforated rings, which tear away during an arc fault explosion. Following an explosive arc fault that damages the arc fault relief panel 102, the panel is merely discarded and replaced with a new one, which is attached and secured to the cabinet in its place via one or more screws or bolts.

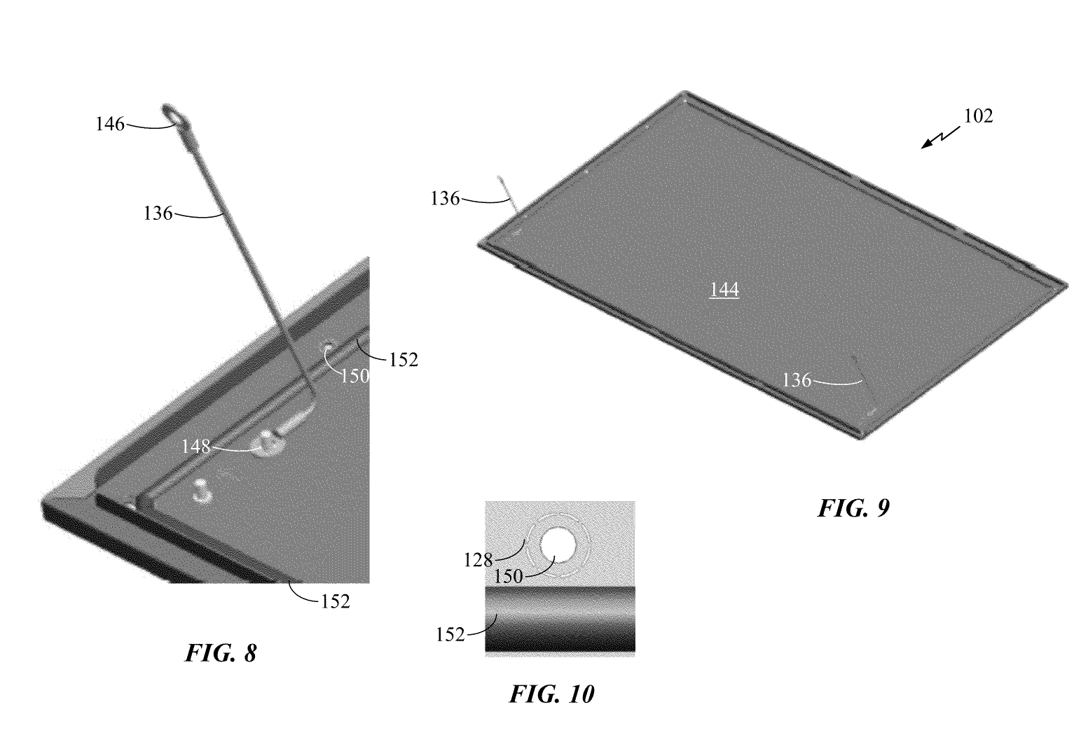

FIGS. 8-10 illustrate the lanyard 136 and various other features of the interior or inner side 144 of the top-mounted arc fault panel 102 of FIGS. 1-7. One end of the lanyard 136 includes a ring 146 that may be welded to a suitable mounting stud within the electrical equipment cabinet. The other end of the lanyard 136 is mounted to inner surface 144 of the panel 102 via a weld stud 148. FIG. 10 shows a close-up of one of the mounting holes 150 through which a screw is mounted. A laser-perforated ring 128 is also shown, which facilitates the tear-away function of the panel. In one particular example, the mounting hole 150 is 8 millimeters (mm) in diameter and the laser-perforated circle 128 is 12 mm in diameter to provide a 7 mm shear tab around the hole. FIG. 10 also shows a portion of a perimeter gasket 152 that helps seal the panel to the cabinet. The gasket 152 is also shown within FIGS. 8 and 9 and extends around the perimeter of the panel 102.

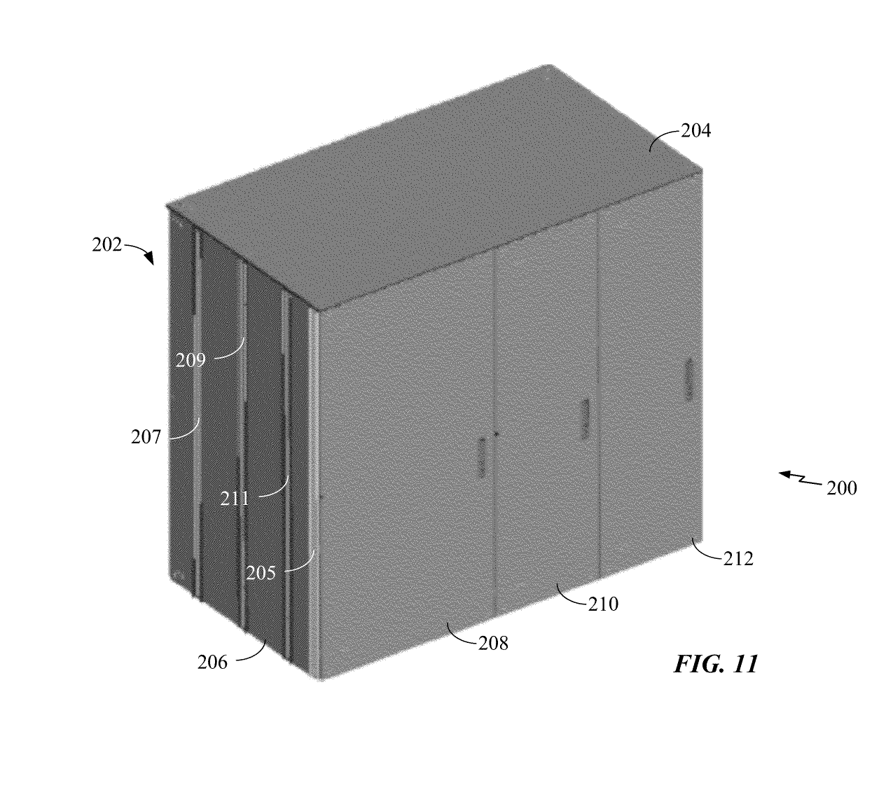

FIG. 11 illustrates a cabinet 200 having a side-mounted arc fault panel 202 formed along a side of a multi-bay enclosure 204 of the cabinet. The cabinet 200 may include electrical equipment not shown in the figure. The panel 202 again includes at least one portion 206 adapted to be bent outwardly during an explosive arc fault to provide an opening for venting pressurized air and heat generated by the arc fault. By relieving pressure within the cabinet 200, the side-mounted arc fault relief panel 202 helps protect other portions of the cabinet from damage such as front panel portions 208, 210 and 212, as well as the electrical equipment itself. In the example of FIG. 11, in addition to an edge-mounted controlled bend location 205 (similar to the controlled bend location 105 of the top-mounted panel described above), the side-mounted panel has with one or more additional bend locations 207, 209 and 211 formed vertically along middle portions of the panel. These additional bend locations may be formed by, for example, providing corresponding slots or relief cuts (not shown in FIG. 11) in the top and bottom edges of the side panel 206 (similar to the relief cut 118 of FIGS. 2 and 3). With these additional slots or relief cuts, the side-panel will also bend or deform along each bend location 207, 209 and 211 so as to provide still further pressure relief.

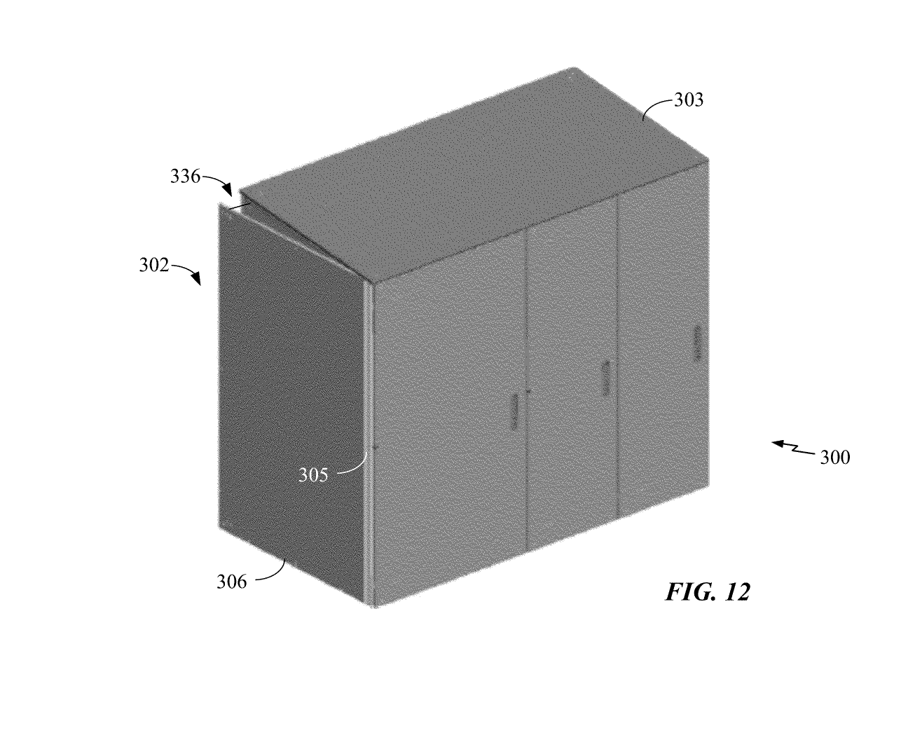

FIG. 12 illustrates a cabinet 300 with a side-mounted arc fault panel 302 formed along a side of a multi-bay enclosure 304 of the cabinet. In this example, the panel 302 includes a single controlled bend location 305 adapted to permit a main portion 306 of the arc fault panel 302 to bent outwardly during an explosive arc fault to provide an opening for release of pressurized air and heat generated by the arc fault. The panel is shown in the exploded position in this figure with the panel bent outwardly. A restraint lanyard 336 is also shown.

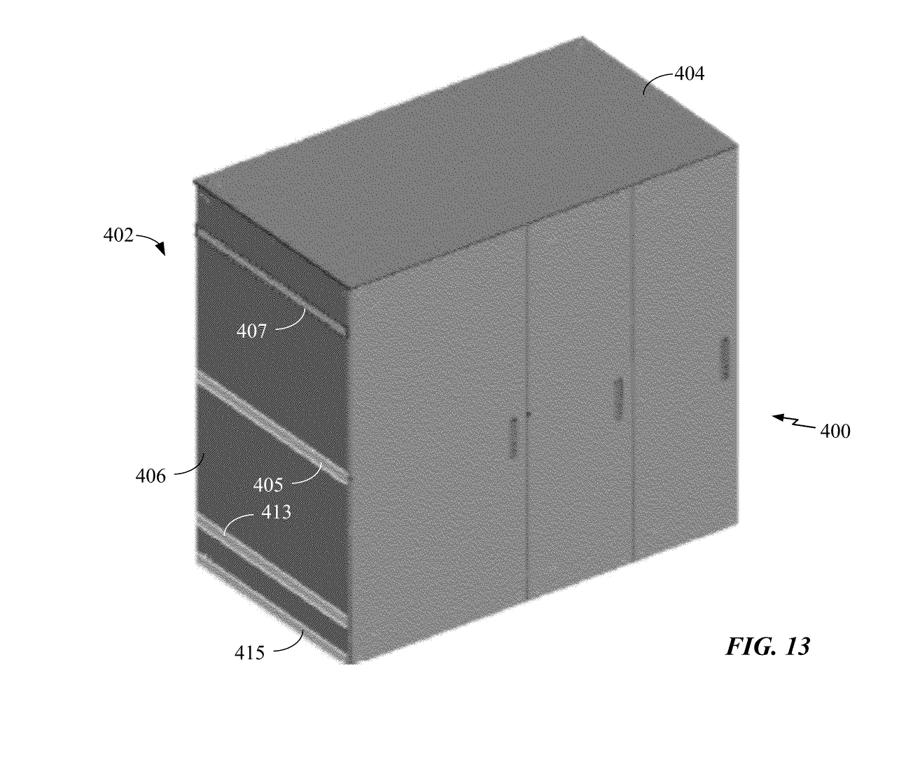

FIG. 13 illustrates a cabinet 400 with a side-mounted arc fault panel 402 formed along a side of a multi-bay enclosure 404 of the cabinet. In this example, the panel 402 includes a primary bend location 405 formed through a middle portion of panel 402. A secondary bend location 407 may also be provided along an upper middle portion of the panel that is closer to a top edge of the panel. Additionally, two panel stiffeners 413 and 415 are provided. Stiffener 413 is formed across a lower middle portion of the panel 402. Stiffener 415 is formed along a bottom edge of the panel 402. These stiffeners may be formed by mounting (or installing or adhering or welding) an additional layer of metal across the panel to strengthen or stiffen the panel to help ensure that the panel bends only along the prescribed controlled bend locations. Hence, as with the stiffeners discussed above (such as bend stiffener 114 of FIG. 1), the stiffeners of FIG. 13 generally help to guide the controlled bending of the panel by strengthening portions of the panel not meant to bend so that the panel will instead bend along predetermined points or lines that have been weakened by, for example, side cuts.

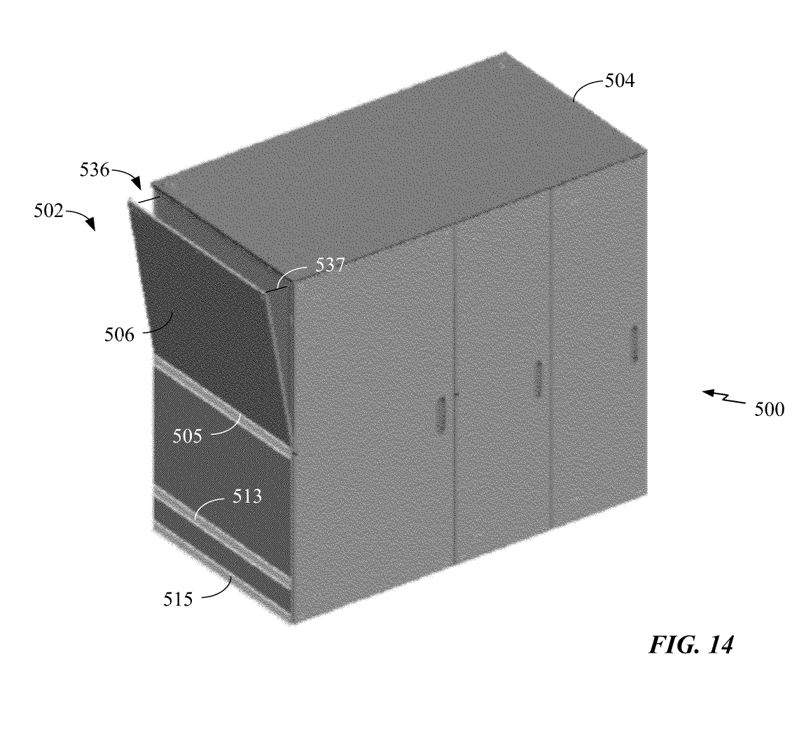

FIG. 14 illustrates another cabinet 500 with a side-mounted arc fault panel 502 formed along a side of a multi-bay enclosure 504 of the cabinet. In this example, the panel 502 includes only a single bend location 505 formed through a middle portion of panel 502. Additionally, two panel stiffeners 513 and 515 are shown. The panel is shown in the open configuration following an explosive arc fault. Two lanyard cables 536 and 537 are also shown, which retrain and limit the outward movement of the panel.

Note that, herein, the term controlled bend location can refer to any segment, portion or sub-portion of the arc fault relief panel that is adapted for controlled and/or predictable deformation. In the examples herein, the controlled bend location is typically a line of weakness that extends across the panel from one edge of the panel, such as controlled bend lines 205, 207, 209 and 211 of FIG. 11. However, in other examples, the controlled bend location may have other shapes or geometries and may cross the panel at other locations or at other angles. In some cases, a particular controlled bend location may not cross the entire panel but only a portion thereof. As such, the controlled bend locations shown and described herein are merely illustrative and exemplary.

In addition to the sides and top of the cabinet, the arc fault panel can also be placed on the front or back, or even the bottom (e.g., if the cabinet is elevated on risers by an amount sufficient to allow it to open and vent air). Still further, multiple arc fault panels may be provided on a single cabinet, with differing shapes, sizes and locations, and with potentially differing features. For example, some panels can be provided with multiple stiffeners whereas others are not.

### Exemplary Apparatus, Devices and Methods

One or more of the components, steps, features, and/or functions illustrated in the figures may be rearranged and/or combined into a single component, step, feature or function or embodied in several components, steps, or functions. Additional elements, components, steps, and/or functions may also be added without departing from the disclosure. The apparatus, devices, and/or components illustrated in the Figures may be configured to perform one or more of the methods, features, or steps described in the Figures.

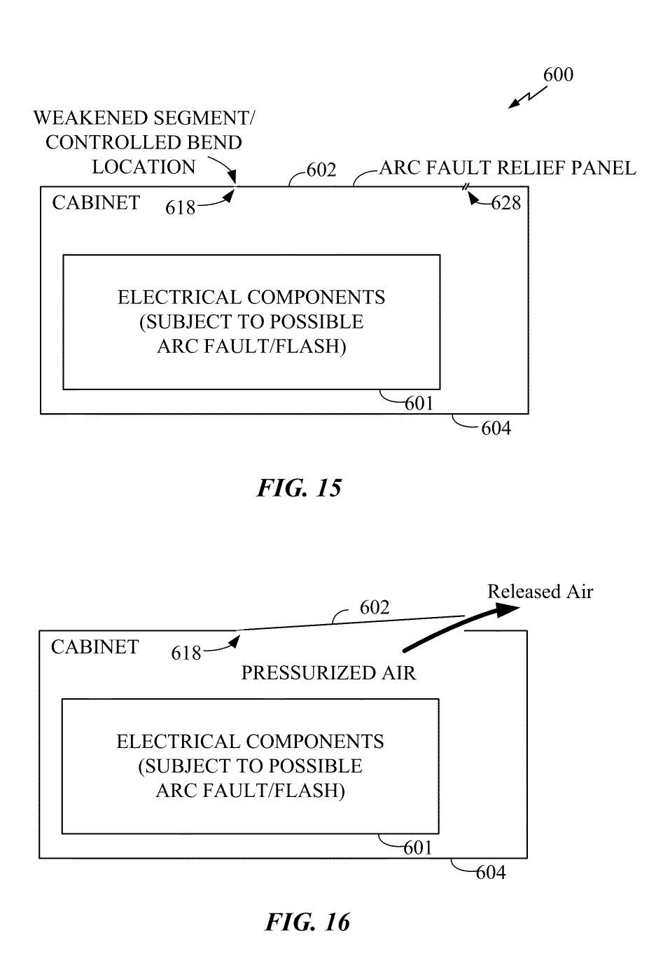

FIGS. 15 and 16 broadly illustrate features of an electrical device or assembly 600 having electrical components 601 (which are subject to a possible arc fault or arc flash) mounted within a cabinet, chassis or enclosure 604. The cabinet 604 includes an arc fault relief panel 602 mounted thereto or attached thereon. At least a portion of the panel provides a weakened segment (i.e. a controlled bend location) 618 for controlled bending or deformation during an explosive arc fault. One or more tear-away connectors or fasteners 628 are provided to facilitate forcible opening of the panel during an explosive arc fault that triggers a burst of air pressure within the cabinet 604. FIG. 16 shows the cabinet during an explosive arc fault that causes pressurized air to deform the panel 602 along weakened segment 618 (e.g., a bend point/line, a segment of deformable material, etc.) and to break/open the tear-away fasteners 628, thereby allowing the panel to open to vent air pressure, heat and gasses. As discussed above, a restraint device such as a lanyard may be provided to restrict the range of movement of the panel during the fault. Moreover, as already explained, multiple weakened segments/controlled bend locations may be provided. Stiffeners may also be used where appropriate to reinforce portions of the arc fault relief panel that are not meant to deform.

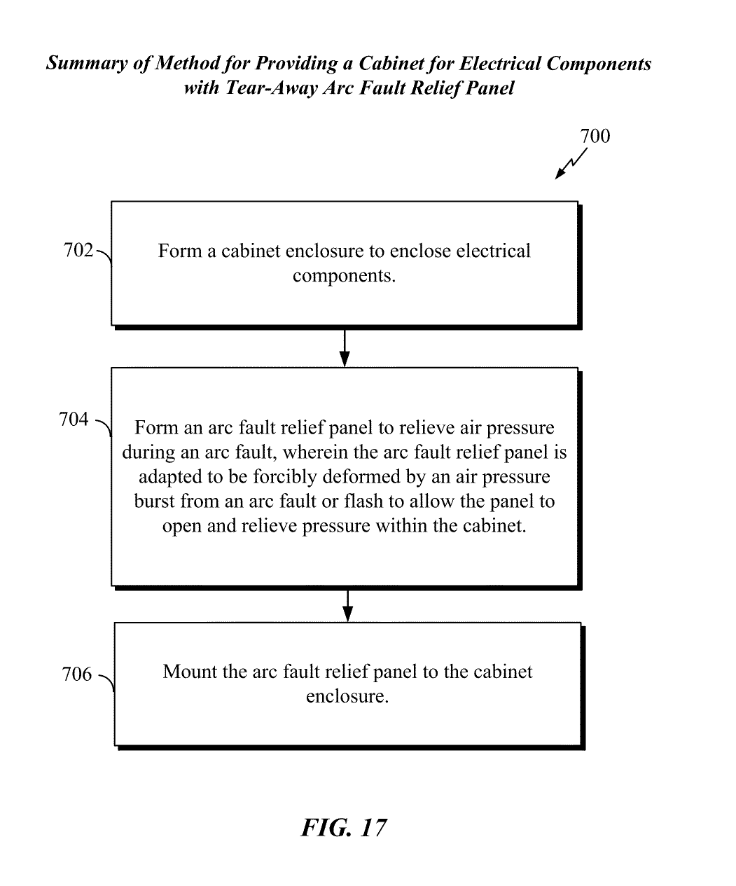

FIG. 17 broadly illustrates and summarizes methods or procedures 700 for providing a cabinet for electrical components that may be used in connection with any of the devices shown in FIGS. 1-16. Briefly, at step 702, a cabinet enclosure is formed or fabricated to enclose electrical components. At step 704, an arc fault relief panel is formed or fabricated to relieve air pressure during an explosive arc fault or arc flash, wherein the arc fault relief panel is adapted to be forcibly deformed by an air pressure burst from an explosive arc fault to allow the panel to open and relieve pressure within the cabinet enclosure. At step 706, the arc fault relief panel is mounted to the enclosure. In some implementations, the fault relief panel may be specifically designed to deform (e.g., bend, twist, fold, crack, break, etc.) from the cabinet enclosure (e.g., either inward or outward) when air inside of the cabinet enclosure reaches a threshold amount of pressure and/or when the air pressure changes faster or more quickly than a threshold amount/percentage (e.g., as in a air pressure burst).

In alternative implementations, the fault relief panel may be specifically designed to partially or fully detach from the cabinet enclosure (e.g., either inward or outward), with or without deforming, when air inside of the cabinet enclosure reaches a threshold amount of pressure and/or when the air pressure changes faster or more quickly than a threshold amount/percentage (e.g., as in an air pressure burst).

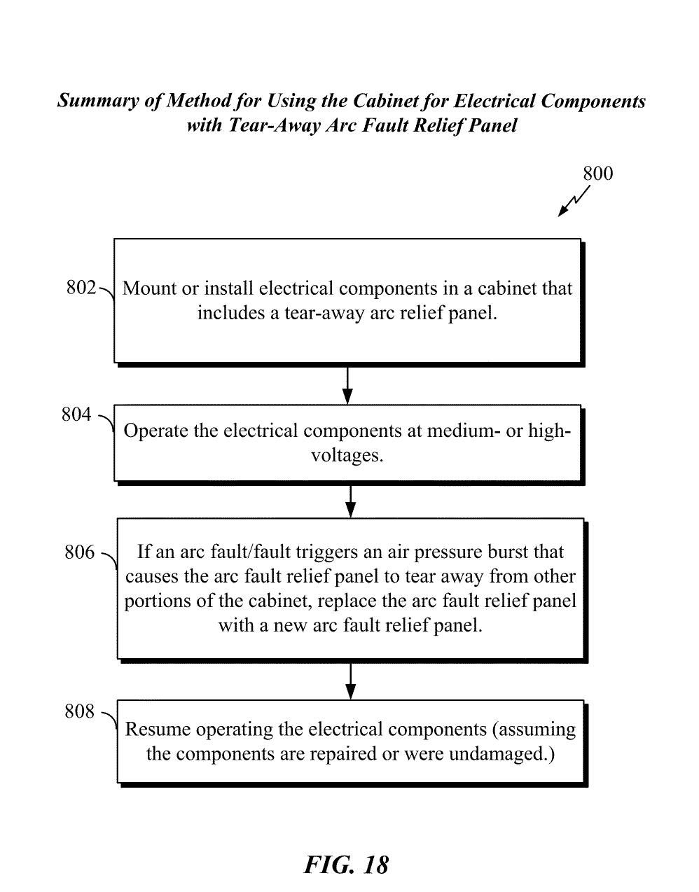

FIG. 18 illustrates methods or procedures 800 for using a cabinet enclosure of the type provided by the steps of FIG. 17. Briefly, at step 802, electrical components are mounted or installed in the cabinet formed with the tear-away arc relief panel. At step 804, the electrical components are operated at medium- or high-voltages. At step 806, if an explosive arc fault/flash triggers an air pressure burst that causes the arc fault relief panel to tear away from other portions of the cabinet, the arc fault relief panel is replaced with a new arc fault relief panel. In an alternative implementation, the arc fault relief panel is reused (if undamaged) or only partially replaced (e.g., only deformed portions, hinges, etc., are replaced). At step 808, the electrical components may be activated to resume operations (e.g., assuming the components are repaired or were undamaged) once the arc fault relief panel is mounted on the cabinet again.

Note that the aspects of the present disclosure may be described herein as a process that is depicted as a flowchart, a flow diagram, a structure diagram, or a block diagram. Although a flowchart may describe the operations as a sequential process, many of the operations can be performed in parallel or concurrently. In addition, the order of the operations may be rearranged. A process is terminated when its operations are completed. A process may correspond to a method, a function, a procedure, a subroutine, a subprogram, etc. When a process corresponds to a function, its termination corresponds to a return of the function to the calling function or the main function.

The various features of the disclosure described herein can be implemented in different systems and devices without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A cabinet for electrical components, comprising:
an enclosure to enclose electrical components; and
an arc fault relief panel to relieve air pressure during an explosive arc fault;
wherein the arc fault relief panel is adapted to be forcibly deformed by an air pressure burst from an explosive arc fault to allow the panel to open and relieve pressure within the cabinet.

2. The cabinet for electrical components of claim 1, wherein the arc fault relief panel includes a weakened portion configured to allow a main portion of the arc fault relief panel to bend away from the enclosure to relieve pressure within the cabinet.

3. The cabinet for electrical components of claim 2, wherein the weakened portion comprises one or more slots formed within the arc fault relief panel to permit controlled bending of the main portion of the arc fault relief panel.

4. The cabinet for electrical components of claim 3, wherein the one or more slots are formed along one or more edges of the arc fault relief panel.

5. The cabinet for electrical components of claim 2, wherein the main portion of the arc fault relief panel is secured to the enclosure using at least one fastener mounted within a tear-away portion of the arc fault relief panel.

6. The cabinet for electrical components of claim 5, wherein the tear-away portion of the arc fault relief panel comprises laser-perforated portions of the arc fault relief panel.

7. The cabinet for electrical components of claim 1, wherein the arc fault relief panel is mounted to a rear of the enclosure.

8. The cabinet for electrical components of claim 1, wherein the arc fault relief panel is mounted to a top of the enclosure.

9. The cabinet for electrical components of claim 1, further including a restraint device to restrict a range of movement of the arc fault relief panel during an explosive arc fault.

10. The cabinet for electrical components of claim 9, wherein the restraint device is a lanyard cable.

11. The cabinet for electrical components of claim 1, further including panel stiffeners formed along portions of the panel not meant to be forcibly deformed.

12. A method for providing a cabinet for electrical components, comprising:
forming an enclosure to enclose electrical components;
forming an arc fault relief panel to relieve air pressure during an explosive arc fault, wherein the arc fault relief panel is adapted to be forcibly deformed by an air pressure burst from an explosive arc fault to allow the panel to open and relieve pressure within the cabinet; and
mounting the arc fault relief panel to the enclosure.

13. The method of claim 12, wherein the arc fault relief panel includes a weakened portion configured to allow a main portion of the arc fault relief panel to bend away from the enclosure to relieve pressure within the cabinet.

14. The method of claim 13, wherein the weakened portion comprises one or more slots formed within the arc fault relief panel to permit controlled bending of the main portion of the arc fault relief panel.

15. The method of claim 14, wherein the one or more slots are formed along one or more edges of the arc fault relief panel.

16. The method of claim 13, wherein the main portion of the arc fault relief panel is secured to the enclosure using at least one fastener mounted within a tear-away portion of the arc fault relief panel.

17. An arc fault relief panel for a cabinet for electrical components, comprising:
an arc fault relief panel configured to relieve air pressure within an enclosure of the cabinet during an explosive arc fault;
wherein the arc fault relief panel is adapted to be forcibly deformed by an air pressure burst from an explosive arc fault within the cabinet to allow the panel to open and relieve pressure within the cabinet; and
wherein the arc fault relief panel includes at least one tear-away portion for fastening a main portion of the panel to the enclosure of the cabinet.
